(19) United States
(12) Patent Application Publication
(10) Pub. No.: US 2026/0113878 A1
(43) Pub. Date: Apr. 23, 2026

(54) COOLANT DISTRIBUTION UNIT

(71) Applicant: LTI Holdings, Inc., Pleasanton, CA (US)

(72) Inventors: Bradley R. Whitney, Epsom, NH (US); John R. Durbin, Spotsylvania, VA (US)

(21) Appl. No.: 19/361,864

(22) Filed: Oct. 17, 2025

Related U.S. Application Data
(60) Provisional application No. 63/709,247, filed on Oct. 18, 2024.

(51) Int. Cl. H05K 7/20

(52) U.S. Cl. CPC H05K 7/20272; H05K 7/20763; H05K 7/20836

(57) ABSTRACT

A coolant distribution unit includes a cabinet including a frame, a top panel, and a plurality of side panels. The coolant distribution unit includes a cooling system at least partially supported by the cabinet, the cooling system including a heat exchanger, and a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, the pump assembly coupled to a bottom of the frame.

### CROSS-REFERENCE TO RELATED APPLICATIONS

This application claims priority to U.S. Provisional Patent Application No. 63/709,247, filed on October 18, 2024, the entire contents of which are incorporated herein by reference.

### FIELD

The present disclosure relates to a coolant distribution unit.

### BACKGROUND

Servers and other computing components for data centers or other facilities that require substantial amounts of computing power typically require cooling systems in order for the servers and other components to operate at optimal temperatures and a coolant distribution unit coupled to the computing components provides a cooling heat exchange to remove heat from the computing components and transfers the heat removed to the ambient environment.

Heat generated by the servers and other components may be transferred to a coolant and exhausted to the ambient air. In order to optimize facility space, a data center may opt to minimize the climate-controlled space in which the servers are stored and locate other components, such as cooling system for the servers, at a remote location, for instance, a mechanical storage room, which may not have a controlled environment.

A coolant distribution unit provides a self-contained apparatus to distribute coolant to servers at a remote location and transfer the heat generated by the servers to another coolant, for instance, another liquid coolant that is distributed throughout the facility and which may be cooled by one of more roof-mounted chillers.

### SUMMARY

The present disclosure provides, in one aspect, a coolant distribution unit coupled to a building chiller system and servers, the coolant distribution unit including: a cabinet including a frame, a top panel, and a plurality of side panels; and a cooling system at least partially supported by the cabinet, the cooling system including a heat exchanger, and a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, the pump assembly coupled to a bottom of the frame.

The present disclosure provides, in another aspect, a coolant distribution unit coupled to a building chiller system and servers, the coolant distribution unit including: a cabinet including a frame, a top panel, and a plurality of side panels; and a cooling system at least partially supported by the cabinet, the cooling system including a heat exchanger, and a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, and wherein at least one of the primary inlet line, primary outlet line, secondary inlet line, and secondary outlet line includes a tolerancing bend joint.

The present disclosure provides, in another aspect, a coolant distribution unit coupled to a building chiller system and servers, the coolant distribution unit including: a cabinet including a frame, a top panel, and a plurality of side panels; and a cooling system at least partially supported by the cabinet, the cooling system including a heat exchanger, and a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, the pump assembly coupled to a bottom of the frame, and a level sensor positioned upstream of the pump assembly configured to monitor a level of coolant flowing into the pump assembly.

Other features and aspects of the subject matter will become apparent by consideration of the following detailed description and accompanying drawings.

### BRIEF DESCRIPTION OF THE DRAWINGS

FIG. 1 is a schematic illustrating a cooling system including a coolant distribution unit.

FIG. 2 is a perspective view of a coolant distribution unit.

FIG. 3 is a perspective view of the coolant distribution unit of FIG. 2.

FIG. 4A is a first portion of a schematic diagram of the coolant distribution unit of FIG. 2.

FIG. 4B is a second portion of a schematic diagram of the coolant distribution unit of FIG. 2.

FIG. 5 is a section view illustrating a pump assembly and the cabinet of the coolant distribution unit of FIG. 2.

FIG. 6 is a perspective view of a pump assembly and filter inlet manifold of the coolant distribution unit of FIG. 2.

Before any embodiments of the subject matter are explained in detail, it is to be understood that the subject matter is not limited in its application to the details of construction and the arrangement of components set forth in the following description or illustrated in the following drawings. The subject matter is capable of other embodiments and of being practiced or of being carried out in various ways. Also, it is to be understood that the phraseology and terminology used herein is for the purpose of description and should not be regarded as limiting.

As used herein, the terms “first”, “second”, and “third” may be used interchangeably to distinguish one component from another and are not intended to signify location or importance of the individual components. The singular forms “a,” “an,” and “the” include plural references unless the context clearly dictates otherwise. The terms “coupled,” “fixed,” “attached to,” and the like refer to both direct coupling, fixing, or attaching, as well as indirect coupling, fixing, or attaching through one or more intermediate components or features, unless otherwise specified herein. As used herein, the terms “comprises,” “comprising,” “includes,” “including,” “has,” “having” or any other variation thereof, are intended to cover a non-exclusive inclusion. For example, a process, method, article, or apparatus that comprises a list of features is not necessarily limited only to those features but may include other features not expressly listed or inherent to such process, method, article, or apparatus. Further, unless expressly stated to the contrary, “or” refers to an inclusive- or and not to an exclusive- or. For example, a condition A or B is satisfied by any one of the following: A is true (or present) and B is false (or not present), A is false (or not present) and B is true (or present), and both A and B are true (or present).

Terms of approximation, such as “generally,” “approximately,” or “substantially,” include values within ten percent greater or less than the stated value. When used in the context of an angle or direction, such terms include within ten degrees greater or less than the stated angle or direction. For example, “generally vertical” includes directions within ten degrees of vertical in any direction, e.g., clockwise or counter-clockwise.

### DETAILED DESCRIPTION

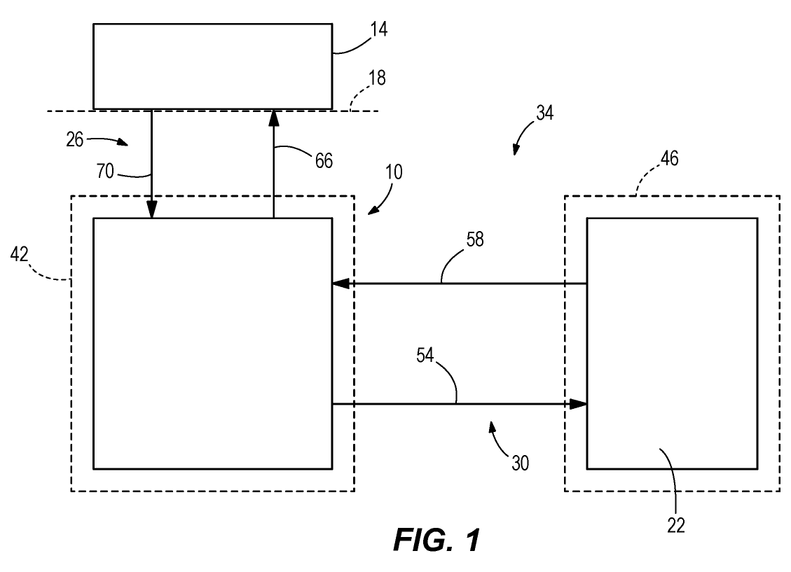

FIG. 1 illustrates a coolant distribution unit 10 (“CDU”) that is fluidly coupled to a building heat exchanger assembly 14 (e.g., a chiller 14 supported by the roof 18 of the building) and to one or more servers 22 and other computing components. The term “servers” will be used throughout to simplify the description, however it should be understood that the term “server” is meant to be non-limiting and used to describe any server, processor, computer, etc. that is cooled by the CDU 10. The CDU 10 is included in and at least partially forms a primary cooling loop with the chiller 14 and a secondary cooling loop 30 with the servers 22. The primary and secondary cooling loops 26, 30 together define a cooling system 34. As will be described in further detail below, the CDU 10 generates a secondary coolant fluid flow through the secondary cooling loop 30 to remove heat from the servers 22 and transfer the generated heat to a primary coolant flowing between the CDU 10 and the chiller 14 to transfer the heat to the ambient air outside of the building. In the present embodiment, the CDU 10 is located in one room 42 (e.g., a non-climate-controlled room) of the building and the one or more servers 22 are located in a separate, climate-controlled room 46.

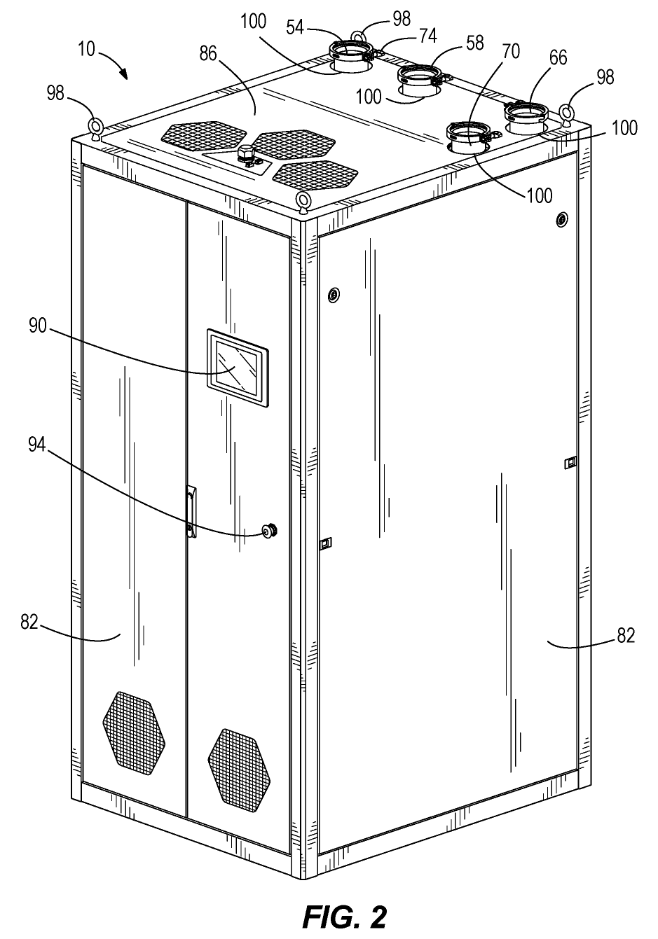

With reference to FIGS. 1-3, 4A and 4B, the CDU 10 includes a cabinet 50 that supports a portion of the cooling system 34 configured to distribute a secondary coolant (e.g., a 75% water / 25% glycol mixture, water, or other coolant) through the secondary cooling loop 30 via a secondary supply line 54 to servers 22 to remove heat from the servers 22 and return the secondary coolant via a secondary return line 58. The heat removed from the servers 22 is transferred to a primary coolant (e.g., water, water/glycol mix, or other coolant) in the primary cooling loop 26 via a heat exchanger 62. The primary coolant in the primary cooling loop 26 flows to the building chiller 14 (for instance, the primary coolant fluid flow is generated by one or more pumps in the building chiller, or elsewhere in the building) via a primary return line 66 that returns the primary coolant to the piping system in the building. The primary coolant in the primary supply line 66 is cooled by the building chiller 14 by removing heat to the ambient air, and the coolant flows back to the CDU 10 as chilled primary coolant via the primary supply line 70, supplying the chilled coolant to the CDU. The secondary supply and return lines 54, 58 and primary return and supply lines 66, 70 are coupled to piping supported in and extending through the building by clamps 74 or other coupling structures.

The cabinet 50 is a rectangular metal enclosure having a frame 78, side panels 82 that maybe selectively removed from frame 78, and a top panel 86. One or more of the side panels 82 support user interfaces (e.g., an input/display screen 90, an emergency shut-off button 94, or other interfaces). The cabinet 50 includes other structures (e.g., casters coupled to the bottom of the frame, not shown, eye bolts 98 coupled to the top of the frame 78) to facilitate moving the CDU 10. The secondary supply and return lines 54, 58 and primary return and supply lines 66, 70 exit the cabinet 50 through holes 100 in the top panel 86 of the cabinet 50.

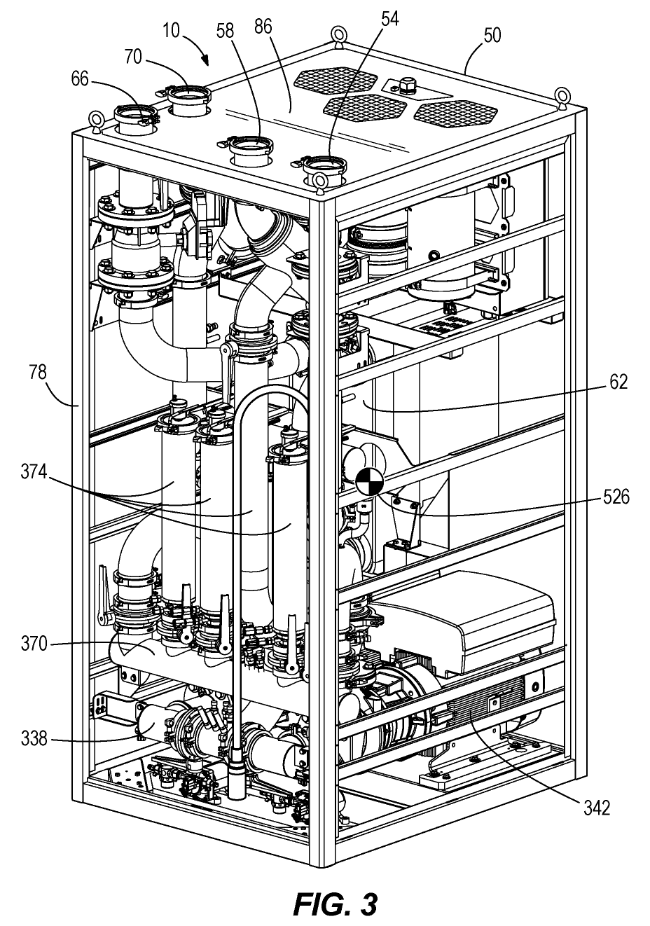

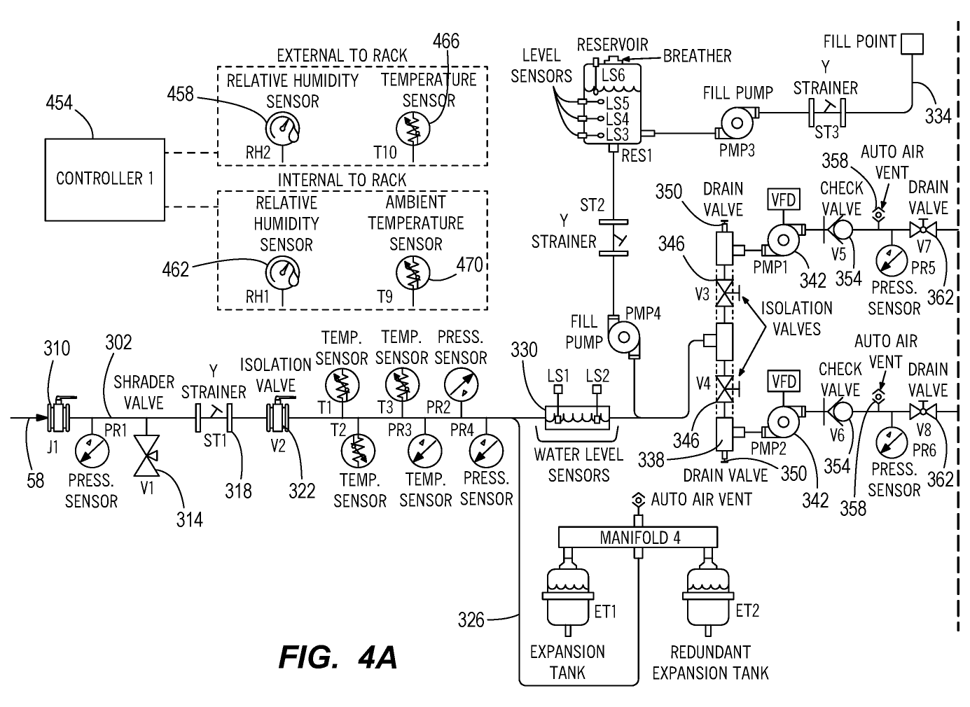

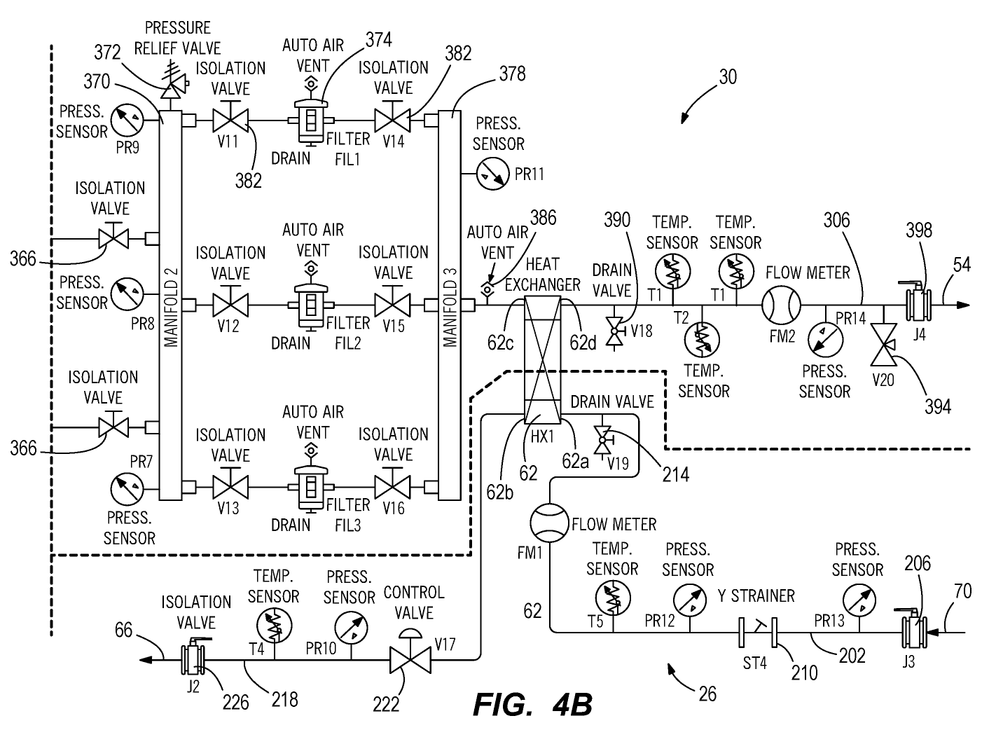

Returning to FIGS. 3, 4A, and 4B, the primary cooling loop 26 includes a primary inlet line 202 coupled to and partially defining the primary supply line 70, and coupled to the heat exchanger 62 at a first heat exchanger inlet 62a. The primary inlet line 202 include an isolation valve 206 and a strainer 210 located downstream of the isolation valve 206 and upstream of the heat exchanger 62. The primary inlet line 202 also includes a drain valve 214 positioned between the strainer 210 and the heat exchanger 62. The primary coolant flows through the heat exchanger 62 from the first heat exchanger inlet 62a to a first heat exchanger outlet 62b and through a primary outlet line 218 coupled to and partially defining the primary return line 66. The primary outlet line 218 includes a control valve 222 and an isolation valve 226 downstream of the control valve 222 and upstream of the primary return line 66, which transfers the primary coolant to the building chiller 14.

With continued reference to FIGS. 3, 4A, and 4B, the secondary cooling loop 30 of the cooling system 34 includes a secondary inlet line 302 coupled to a second heat exchanger inlet 62c and a secondary outlet line 306 coupled to a second heat exchanger outlet 62d. The secondary inlet line 302 and secondary outlet line 306 at least partially define the secondary return line 58 and secondary supply lines 54, respectively.

The secondary inlet line 302 includes an isolation valve 310, a port 314 (e.g., a Shrader port) downstream of the isolation valve 310, a strainer 318 that filters the secondary coolant upon return from the servers 22, and an isolation valve 322. An expansion tank branch 326 is coupled to the secondary inlet line 302 downstream of the second isolation valve 322. Downstream of the expansion tank branch 326 are coolant level sensors 330, a fill branch 334 extending from the secondary inlet line 302, and a pump manifold 338. The level sensors 330 monitor the level of secondary coolant into the pump manifold 338 to ensure there is secondary coolant flowing into the pump manifold 338. In some embodiments, the secondary coolant can be drained from the port 314. In other embodiments, a view port, clear tube, or other viewing structure can be coupled to the port 314 to check the fluid level in the CDU 10. In still other embodiments, an additional sensor (e.g., a pressure sensor) can be coupled to the port 314.

One or more pump assemblies 342 (e.g., two pump assemblies) are coupled to the pump manifold 338. The pump manifold 338 includes isolation valves 346 and drain valves 350 corresponding to each of the pump assemblies 342. A check valve 354, an auto air vent 358, a drain valve 362, and an isolation valve 366 are positioned downstream of each pump assembly 342. Each pump assembly 342 generates a flow of the secondary coolant into a filter inlet manifold 370. The filter inlet manifold includes a pressure relief valve 372. One or more filter assemblies 374 (e.g., three filter assembles) are coupled to the filter inlet manifold 370 and to a filter outlet manifold 378. Isolation valves 382 are positioned between the filter inlet manifold 370 and each filter assembly 374, and between each filter assembly 374 and the filter outlet manifold 378. The filter outlet manifold 378 is coupled to the second heat exchanger inlet 62c and an air vent 386 is positioned between the filter outlet manifold 378 and the second heat exchanger inlet 62c. The secondary coolant flows into the second heat exchanger inlet 62c and exits the heat exchanger 62 at the second heat exchanger outlet 62d. A drain valve 390, port 394, and isolation valve 398 are positioned in the secondary outlet line 306 downstream of the heat exchanger 62 and leading to the secondary supply line 54.

The cooling system 34 includes sensors (e.g., pressure sensors, temperature sensors, flow rate sensors, and level sensors) coupled to or positioned in the primary inlet line 202, primary outlet line 218, secondary inlet line 302, and secondary outlet line 306 to continuously monitor conditions of the primary and secondary coolants in the CDU 10. The sensors provide signals to a controller 454 to monitor operation of the CDU 10. The CDU 10 includes other sensors that provide signals indicating conditions external and internal to the CDU 10 (relative humidity sensors 458, 462 and ambient temperature sensors 466, 470 that indicate the external and internal relative humidity and temperature of the CDU). Other sensors and valves may be included to monitor and control operation of the CDU.

The isolation valves of the primary inlet line 202, primary outlet line 218, secondary inlet line 302, and secondary outlet line 306 are configured as manually operable valves. In other embodiments, the valves may be actuated by the controller 454. The valves may be ball valves, throttle plate valves, or any other appropriate valve, or a combination thereof. It will be appreciated that the positioning of the isolation valves in the primary inlet line 202, primary outlet line 218, secondary inlet line 302, and secondary outlet line 306 allow various components positioned between pairs of isolation valves to be removed from the primary inlet line 202, primary outlet line 218, secondary inlet line 302, and secondary outlet line 306, e.g., during a service process, while limiting the potential loss of primary and secondary coolant.

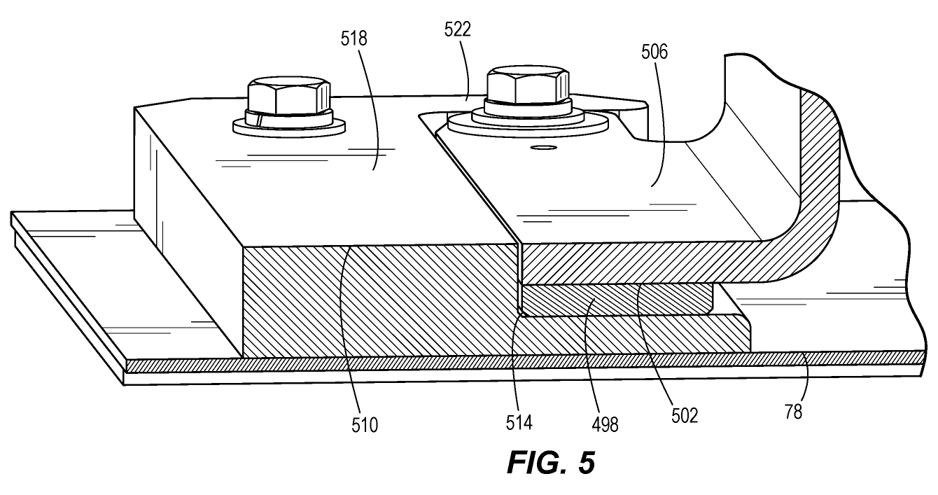

With reference to FIGS. 3 and 5, the pump assemblies 342 are coupled to the bottom of the frame 78 of the cabinet 50. The pump assemblies may be a positive displacement pump or any other appropriate type of pump assembly. Each pump assembly 342 includes slide inserts 498 coupled to the bottom face 502 of the pump support brackets 506. The cabinet 50 also includes slide supports 510 positioned on the base of the frame 78 in facing relationship with the slide inserts 498. The slide supports 510 guide the pump assembly 342 during a replacement procedure. The slide supports 510 include an open end 514, a side guide 518 and an end stop 522. A new/replacement pump assembly 342, as provided in a service kit, includes slide inserts 498 coupled to the bottom 502 of the pump support brackets 506 that permits the pump assembly 342 to slide along the slide supports 510. The slide inserts 498 and slide supports 510 may be formed of a high-density plastic that has a reduced sliding friction coefficient in comparison to the friction coefficient between, for instance, two steel components.

It will be appreciated that by mounting the pump assemblies 342 to the bottom of the cabinet 50, the center of gravity 526 of the CDU 10 is positioned at a lower location in the cabinet (e.g., a distance from the ground that is less than half of the height of the cabinet 50), which reduces the likelihood that the CDU 10 would tip over as a result of an external force applied to the cabinet (e.g., during service, earthquake conditions, etc.). The low positioning of the pump assemblies 342 also reduces the need to operate a lift fixture to lower the pump assembly 342 onto a cart following removal, and lift a new pump assembly 342 to a raised position for installation. Furthermore, by including slide inserts 498 on the pump assembly and slide supports 510 in the cabinet 50, the CDU 10 does not require drawer slides, reducing the complexity of the CDU.

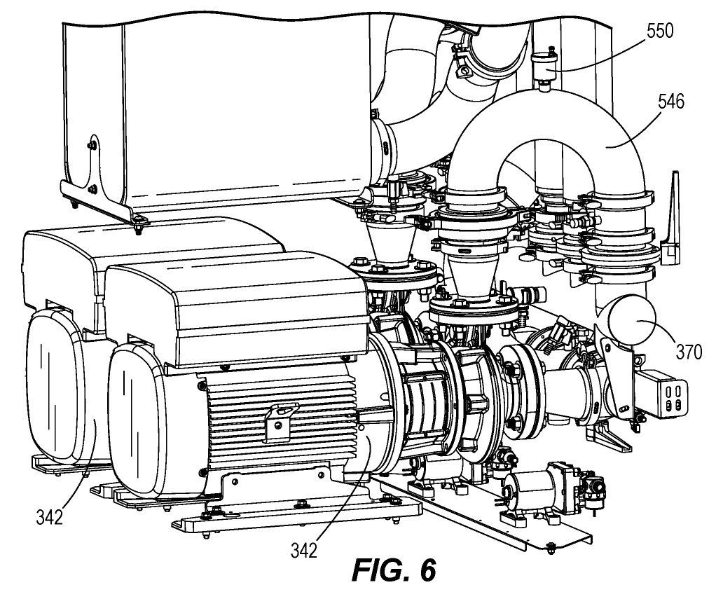

With reference to FIG. 6, the cooling system 34 also includes other joint configurations to allow for tolerance between the locations for various components. In the present embodiment, the cooling system 34 includes a tolerancing bend. The tolerancing bend is 180° U-bend pipe section 546 between each of the pump assemblies 342 and the filter inlet manifold 370. Each pipe section 546 includes an auto air breather 550 positioned at the high point of the pipe section 546. It will be appreciated that the U-bend pipe section 546 accommodates tolerances between the location of the pump assembly 342 and the filter inlet manifold 370 by allowing for vertical movement (e.g., the height tolerance of the pump assembly outlet in relation to the bottom of the slide insert 498 on the pump support bracket 506. The U-bend pipe section 546 also permits variation of the position of the pump assembly 342 in relation to the horizontal position of the filter inlet manifold 370, for instance, due to tolerance of the slide inserts 498 and slide supports 510. The U-bend pipe section 546 therefore permits adjustment of position and coupling of the pump assembly 342 and filter inlet manifold 370 in three degrees of freedom.

Although the subject matter has been described in detail with reference to certain preferred embodiments, variations and modifications exist within the scope and spirit of one or more independent aspects of the subject matter as described. Various features of the subject matter are set forth in the following claims.

What is claimed is:

1. A coolant distribution unit coupled to a building chiller system and servers, the coolant distribution unit comprising:
a cabinet including a frame, a top panel, and a plurality of side panels; and
a cooling system at least partially supported by the cabinet, the cooling system including a heat exchanger, and
a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, the pump assembly coupled to a bottom of the frame.

2. The coolant distribution unit of claim 1, wherein the coolant distribution unit defines a center of gravity, the center of gravity positioned at a distance from the bottom that is less than half of a height defined by the cabinet.

3. The coolant distribution unit of claim 2, wherein the cabinet includes a slide support coupled to the frame and the pump assembly includes a slide insert coupled to a support bracket, wherein the slide insert and the slide support are in facing relationship.

4. The coolant distribution unit of claim 3, wherein the slide insert is composed of a high-density plastic.

5. The coolant distribution unit of claim 1, wherein at least one of the primary inlet line, primary outlet line, secondary inlet line, and secondary outlet line includes a tolerancing bend joint.

6. The coolant distribution unit of claim 5, wherein the tolerancing bend joint includes a 180-degree U bend.

7. The coolant distribution unit of claim 6, wherein the tolerancing bend joint includes an air breather.

8. The coolant distribution unit of claim 1, further comprising a level sensor positioned upstream of the pump assembly configured to monitor a level of coolant flowing into the pump assembly.

9. A coolant distribution unit coupled to a building chiller system and servers, the coolant distribution unit comprising:
a cabinet including a frame, a top panel, and a plurality of side panels; and
a cooling system at least partially supported by the cabinet, the cooling system including
a heat exchanger, and
a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, and
wherein at least one of the primary inlet line, primary outlet line, secondary inlet line, and secondary outlet line includes a tolerancing bend joint.

10. The coolant distribution unit of claim 9, wherein the tolerancing bend joint permits positioning in three degrees of freedom.

11. The coolant distribution unit of claim 10, wherein the tolerancing bend joint includes a 180-degree U bend.

12. The coolant distribution unit of claim 10, wherein the tolerancing bend joint is positioned downstream of the pump assembly.

13. The coolant distribution unit of claim 10, wherein the tolerancing bend joint includes an air breather to permit egress of air.

14. The coolant distribution unit of claim 13, wherein the air breather is positioned at a high point of the tolerancing bend joint.

15. The coolant distribution unit of claim 10, further comprising a level sensor positioned upstream of the pump assembly configured to monitor a level of coolant flowing into the pump assembly.

16. A coolant distribution unit coupled to a building chiller system and servers, the coolant distribution unit comprising:
a cabinet including a frame, a top panel, and a plurality of side panels; and
a cooling system at least partially supported by the cabinet, the cooling system including
a heat exchanger, and
a primary inlet line, a primary outlet line, a secondary inlet line, and a secondary outlet line, each of which are coupled to the heat exchanger, the secondary inlet line including a pump assembly configured to generate a coolant flow through the secondary inlet line and the secondary outlet line, the secondary inlet line further include one or more filter assemblies configured to filter a coolant, the pump assembly coupled to a bottom of the frame, and
a level sensor positioned upstream of the pump assembly configured to monitor a level of coolant flowing into the pump assembly.

17. The coolant distribution unit of claim 16, wherein the secondary inlet line includes a tolerancing bend joint positioned downstream of the pump assembly.

18. The coolant distribution unit of claim 17, wherein the coolant distribution unit defines a center of gravity, the center of gravity positioned at a distance from the bottom that is less than half of a height defined by the cabinet.

19. The coolant distribution unit of claim 17, wherein the cabinet includes a slide support coupled to the frame and the pump assembly includes a slide insert coupled to a support bracket, wherein the slide insert and the slide support are in facing relationship, the slide insert composed of a high-density plastic.
